(19) United States
(12) Patent Application Publication
(10) Pub. No.: US 2024/0283406 A1
(43) Pub. Date: Aug. 22, 2024

(54) AMPLIFIER CIRCUIT AND METHOD OF OPERATING AMPLIFIER CIRCUIT

(71) Applicant: Telefonaktiebolaget LM Ericsson (publ), Stockholm (SE)

(72) Inventors: Rui HOU, Täby (SE); Richard HELLBERG, Huddinge (SE); Andre BLEKER, Bålsta (SE)

(73) Assignee: Telefonaktiebolaget LM Ericsson (publ), Stockholm (SE)

(21) Appl. No.: 18/571,211

(22) PCT Filed: Mar. 22, 2022
(86) PCT No.: PCT/SE2022/050271

§ 371 Date: Dec. 15, 2023

Related U.S. Application Data
(60) Provisional application No. 63/217,094, filed on Jun. 30, 2021.

(51) Int. Cl. H03F 1/02; H01P 5/18; H03F 3/24

(52) U.S. Cl. CPC H03F 1/0288; H01P 5/18; H03F 3/245; H03F 2200/204; H03F 2200/451

(57) ABSTRACT

An amplifier circuit is comprising a first amplifier configured to receive a first signal, a second amplifier configured to receive a second signal, a third amplifier configured to receive a third signal, and a directional coupler. An output of the first amplifier is connected to a first port of the directional coupler, an output of the third amplifier is connected to a second port of the directional coupler, an output of the second amplifier is connected to a third port of the directional coupler, and a fourth port of the directional coupler is connected to an output of the amplifier circuit. The directional coupler is configured such that different proportions of output signals of the second and third amplifiers are coupled to the first port of the directional coupler.

### TECHNICAL FIELD

Examples of this disclosure include an amplifier circuit, and a method of operating an amplifier circuit

### BACKGROUND

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

In a wireless communication system, a transmitter employs power amplifiers (PA) to boost signal power for radio transmission. To be efficient in occupying frequency spectrum, modern communication signals have a large peak-to-average power ratio (PAPR). The capability to reach peak power and to maintain energy efficiency at average power levels are contradictory for conventional (single branch) PAs. More sophisticated PA architectures employ multiple PA branches to satisfy both the power and the efficiency requirements. Among these PA architectures, the most widely used in wireless infrastructures is the Doherty PA.

A Doherty PA comprises of at least 2 PA branches, namely the main and the auxiliary branch. In operation, the auxiliary PA injects power into the main PA to modulate its effective load impedance in a specific pattern (hereafter referred to as Doherty load modulation), such that total efficiency is maximized not only at the peak-power but also at the average-power level.

Either the main or the auxiliary amplifier branch can be implemented as a balanced amplifier, yielding a PA architecture called load modulated balanced amplifier (LMBA). A balanced amplifier employs two identical amplifier branches, processing signals with identical magnitudes but 90 degrees out of phase. The 90-degree phase difference is often implemented by using 3-dB 90-degree hybrid couplers at the input (as a power splitter) and output (as a power combiner).

One way to implement LMBA is known as sequential LMBA (S-LMBA), which employs a main amplifier branch and two identical auxiliary amplifier branches in a balanced configuration, and is described for example in J. Pang et al., “Analysis and Design of Highly Efficient Wideband RF-Input Sequential Load Modulated Balanced Power Amplifier,” IEEE Transactions on Microwave Theory and Techniques, vol. 68, no. 5, pp. 1741-1753, May 2020 [1]. The main amplifier injects power into the isolated port of the hybrid coupler at the output of the balanced auxiliary amplifiers. The power from the auxiliary amplifiers cannot reach the main amplifier at the isolated port. As such, the main amplifier cannot experience load modulation.

To enable load modulation for the main amplifier in the S-LMBA configuration, a technique, namely asymmetrical LMBA (A-LMBA), is described for example in Y. Cao, H. Lyu, and K. Chen, “Asymmetrical Load Modulated Balanced Amplifier With Continuum of Modulation Ratio and Dual-Octave Bandwidth,” IEEE Transactions on Microwave Theory and Techniques, vol. 69, no. 1, pp. 682-696, January 2021 [2]. In this technique, the two auxiliary amplifiers are not identical, causing unequal power output. This power difference from the two unequal auxiliary amplifiers is delivered to the isolated port of the 3-dB hybrid coupler (the power combiner), where the output of the main amplifier is connected. As such, A-LMBA can achieve a continuum of load modulation ratios. In one extreme case of this continuum, the two auxiliary amplifiers are identical, then A-LMBA degenerates into S-LMBA, and the load modulation for the main amplifier is eliminated. In the other extreme case, the imbalance of the two auxiliary amplifiers reaches the extreme, i.e. the power from one auxiliary branch becomes twice as large whereas the power from the other auxiliary branch becomes zero. In this case, the A-LMBA degenerates into a Doherty PA.

In the formulation of [2], both S-LMBA and Doherty can be seen as special cases of A-LMBA.

### SUMMARY

A first aspect of this disclosure provides an amplifier circuit comprising a first amplifier configured to receive a first signal, a second amplifier configured to receive a second signal and a third amplifier configured to receive a third signal, and a first directional coupler. An output of the first amplifier is connected to a first port of the first directional coupler, an output of the third amplifier is connected to a second port of the first directional coupler, an output of the second amplifier is connected to a third port of the first directional coupler, and a fourth port of the first directional coupler is connected to an output of the amplifier circuit. The directional coupler is configured such that different proportions of output signals of the second and third amplifiers are coupled to the first port of the directional coupler.

Another aspect of this disclosure provides a method of operating an amplifier circuit. The amplifier circuit comprises a first amplifier configured to receive a first signal, a second amplifier configured to receive a second signal and a third amplifier configured to receive a third signal, and a first directional coupler. An output of the first amplifier is connected to a first port of the first directional coupler, an output of the third amplifier is connected to a second port of the first directional coupler, an output of the second amplifier is connected to a third port of the first directional coupler, and a fourth port of the first directional coupler is connected to an output of the amplifier circuit. The first, second and third signals are based on a signal to be amplified by the amplifier circuit, and the directional coupler is configured such that different proportions of output signals of the second and third amplifiers are coupled to the first port of the directional coupler. The method comprises operating the amplifier circuit in a first output amplitude range in which the second and third amplifiers are substantially switched off and a amplitude of an output signal of the first amplifier increases substantially linearly across the first output amplitude range.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 is a schematic of an example of an amplifier circuit according to embodiments of this disclosure;

FIG. 2 is a flow chart of an example of a method of operating an amplifier circuit according to embodiments of this disclosure;

FIG. 3 shows an example of an amplifier circuit according to embodiments of this disclosure;

FIG. 4 illustrates an example of output current of three transistors vs. normalized input voltage in an example of the operation of an exemplary embodiment of an amplifier circuit;

FIG. 5 illustrates an example of the output voltage of the three transistors vs. normalized input voltage in the example of the operation of an exemplary embodiment of an amplifier circuit;

FIG. 6 illustrates an example of the load resistance seen by the three transistors vs. normalized input voltage in the example of the operation of an exemplary embodiment of an amplifier circuit; and

FIG. 7 illustrates an example of efficiency of the three transistors and the total efficiency vs. normalized input voltage in the example of the operation of an exemplary embodiment of an amplifier circuit.

### DETAILED DESCRIPTION

The following sets forth specific details, such as particular embodiments or examples for purposes of explanation and not limitation. It will be appreciated by one skilled in the art that other examples may be employed apart from these specific details. In some instances, detailed descriptions of well-known methods, nodes, interfaces, circuits, and devices are omitted so as not obscure the description with unnecessary detail. Those skilled in the art will appreciate that the functions described may be implemented in one or more nodes using hardware circuitry (e.g. analog and/or discrete logic gates interconnected to perform a specialized function, Application Specific Integrated Circuits (ASICs), Programmable Logic Arrays (PLAs), etc.) and/or using software programs and data in conjunction with one or more digital microprocessors or general purpose computers. Nodes that communicate using the air interface also have suitable radio communications circuitry. Moreover, where appropriate the technology can additionally be considered to be embodied entirely within any form of computer-readable memory, such as solid-state memory, magnetic disk, or optical disk containing an appropriate set of computer instructions that would cause a processor to carry out the techniques described herein.

Hardware implementation may include or encompass, without limitation, digital signal processor (DSP) hardware, a reduced instruction set processor, hardware (e.g. digital or analogue) circuitry including but not limited to application specific integrated circuit(s) (ASIC) and/or field programmable gate array(s) (FPGA(s)), and (where appropriate) state machines capable of performing such functions.

There currently exist certain challenges. In particular, for example, Doherty load modulation directly relates the load modulation ratio to the back-off power level where efficiency enhancement is achieved. Modern communication signals have large PAPRs (e.g. 7-9 dB). Doherty PAs optimized for these signals need to achieve a load modulation ratio of 2.5-3.

A high load modulation ratio as such degrades efficiency due to shunt losses and quiescent current loss in the main amplifier. Furthermore, output parasitic capacitance of the main transistor and a high load impedance fundamentally limit the operating bandwidth due to the Bode-Fano criteria.

At the other extreme, S-LMBA has a load modulation ratio of 1 (i.e. no load modulation at all) for the main amplifier. This is also sub-optimal for efficiency enhancement, since practical transistors have non-zero channel resistances. This resistance and the load resistance at the intrinsic current generator plane form a resistive voltage divider. A moderate increase of load resistance reduces the voltage on the channel resistance, thereby improves PA efficiency. S-LMBA cannot achieve this moderate increase of load resistance for the main amplifier, therefore has a sub-optimal efficiency at power back-off. Furthermore, the main transistor in S-LMBA is hard clipped above the back-off power level, causing severe non-linearity and reliability risks.

Load-pull measurement of modern transistors yields different load resistances for maximum efficiency and maximum power. Their ratio is around 1.5, i.e. a load modulation ratio around 1.5 yields maximum efficiency at the back-off power level as well as maximum power at the peak power level.

A-LMBA can achieve the aforementioned deep back-off (e.g. 7-9 dB PAPR) and a moderate load modulation ratio (e.g. 1.5). It further relaxes the hard compression of the main amplifier. However, A-LMBA requires two different auxiliary amplifiers with different power capabilities. If identical transistors are used, some power capabilities of one auxiliary amplifier are under-utilized. For example, in [2], the supply voltage of one auxiliary amplifier is lowered. This under utilization of power capability is a cost overhead. To avoid this cost overhead, another way to implement A-LMBA is to use two auxiliary transistors with different gate peripheries. This solution increases the bill of materials and complicates the transistor 25 supply.

Certain aspects of the present disclosure and their embodiments may provide solutions to these or other challenges. For example, examples of this disclosure may provide an amplifier circuit and a method that enables load modulation of the main amplifier in an amplifier circuit that has an arrangement that appears similar to A-LMBA. This may enable the same benefits as an A-LMBA. However, different from A-LMBA, examples of this disclosure may employ two identical auxiliary amplifier branches, and fully utilize the power capability of each auxiliary branch. This may be achieved for example by using an imbalanced directional coupler to combine the outputs of the auxiliary amplifiers, such that for example different proportions of the output signals of the auxiliary amplifiers are coupled to the output of the main amplifier. For example, examples may use a directional coupler with a coupling factor other than 3 dB, where a 3 dB coupling factor indicates that a signal provided to a port of a directional coupler is split equally between two other ports (e.g. a signal provided to the input port is split equally between transmitted and coupled ports). Therefore, in examples of this disclosure, the equal powers from identical auxiliary amplifiers are not fully cancelled at the isolated port of the coupler. The residue power is injected to the main amplifier at the isolated port to achieve load modulation for the main amplifier.

Certain embodiments may provide one or more of the following technical advantages. For example, compared with Doherty PAs and LMBAs with Doherty modulation ratio, examples of the present disclosure may achieve efficiency enhancement at deep power back-off levels without using a large load modulation ratio. This reduction in load modulation ratio may mitigate efficiency degradations due to shunt loss and quiescent current. Furthermore, this reduction in load modulation ratio may broaden the operating bandwidth due to the Bode-Fano criteria.

Compared with S-LMBA, examples of the present disclosure may enable a moderate load modulation for the first (e.g. main) amplifier. A moderate increase of load resistance may reduce the voltage on the channel resistance, thereby improves PA efficiency. Furthermore, examples of the present disclosure may avoid the hard compression of the main amplifier in an S-LMBA. This may further avoid severe non-linearity and mitigate reliability issues.

Compared with A-LMBA, which uses two different auxiliary amplifiers, examples of the present disclosure may employ two identical second and third (e.g. auxiliary) amplifiers, and still fully utilize their power capabilities. This may reduce the number of transistor variants for a certain design and the associated supply complexity, and may also avoid cost overhead due to under-utilizing the power capability of transistors.

Some of the embodiments contemplated herein will now be described more fully with reference to the accompanying drawings. Embodiments are provided by way of example to convey the scope of the subject matter to those skilled in the art.

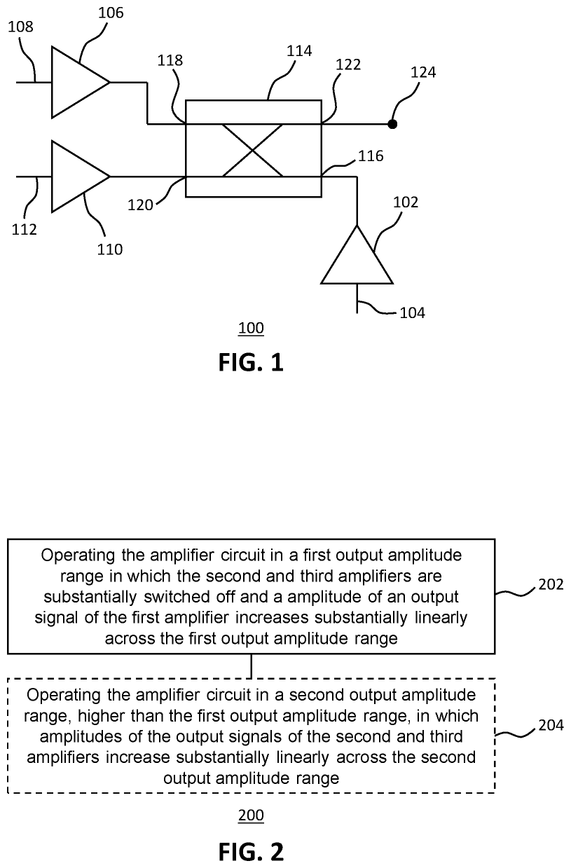

FIG. 1 is a schematic of an example of an amplifier circuit 100 according to embodiments of this disclosure. The amplifier circuit 100 comprises a first amplifier 102 configured to receive a first signal (e.g. at its input 104). The amplifier circuit 100 also comprises a second amplifier 106 configured to receive a second signal (e.g. at its input 108) and a third amplifier 110 configured to receive a third signal (e.g. at its input 112).

The amplifier circuit also includes a first directional coupler 114. An output of the first amplifier 102 is connected to a first port 116 of the first directional coupler 114, and an output of the third amplifier 110 is connected to a second port 120 of the first directional coupler 114. An output of the second amplifier 106 is connected to a third port 118 of the first directional coupler 114, and a fourth port 122 of the first directional coupler is connected to an output 124 of the amplifier circuit.

The directional coupler 114 is configured such that different proportions of output signals (e.g. output currents) of the second 106 and third 110 amplifiers are coupled to the input port 116 of the directional coupler 114. For example, the directional coupler 114 is configured such that the output signals of the second 106 and third 110 amplifiers only partially cancel at the input port 116 of the directional coupler 114 (e.g. the port to which the output of the first amplifier 102 is connected). In some examples, the coupling factor of the directional coupler is a value other than 3 dB (e.g. a signal provided to the first port of the directional coupler 114 may be split unequally between the second and third ports). Thus, for example, in embodiments of this disclosure, some signal from the second 106 and third 110 amplifiers reaches the first amplifier 102 and provides load modulation to the first amplifier 102.

In some examples, the first port comprises an input port of the first directional coupler, the second port comprises a transmitted port of the first directional coupler, the third port comprises a coupled port of the first directional coupler, and the fourth port comprises an isolated port of the first directional coupler. Alternatively, for example, the first port comprises a transmitted port of the first directional coupler, the second port comprises an input port of the first directional coupler, the third port comprises an isolated port of the first directional coupler, and the fourth port comprises a coupled port of the first directional coupler. In other examples, the first port comprises a coupled of the first directional coupler, the second port comprises an isolated port of the first directional coupler, the third port comprises an input port of the first directional coupler, and the fourth port comprises a transmitted port of the first directional coupler. In other examples, the first port comprises an isolated port of the first directional coupler, the second port comprises a coupled port of the first directional coupler, the third port comprises a transmitted port of the first directional coupler, and the fourth port comprises an input port of the first directional coupler. Thus for example the directional coupler 114 may be connected in the amplifier circuit 100 in various ways to provide the operations and advantages described herein.

In some examples, the second and third amplifiers are substantially identical or identical. For example, they may use substantially identical or identical transistors (e.g. the same size transistors). This may simplify the amplifier circuit compared to for example other arrangements where different second 106 and third 110 amplifiers or different transistors are used.

The first, second and third signals are based on a signal to be amplified by the amplifier circuit 100. That is, for example, the first, second or third signals may each comprise the third signal that is scaled, offset and/or phase shifted as appropriate.

In some examples, the second signal is substantially identical or identical to the third signal, and substantially 90 degrees out of phase with the third signal. The amplifier circuit 100 may in some examples be configured to operate in a first output amplitude range. The output amplitude of the amplifier circuit 100 may be for example the output (or peak output) for a given amplitude of signal to be amplified, and may be affected for example by a power or gain setting of the amplifier circuit 100. In the first output amplitude range (e.g. from zero to a first output amplitude), the second 106 and third 110 amplifiers are substantially switched off and the amplitude of an output signal (e.g. output current) of the first amplifier 102 increases substantially linearly across the first output amplitude range. The amplifier circuit 100 may also in some examples be configured to operate in a second output amplitude range (e.g. from the first output amplitude to a second output amplitude), higher than the first output amplitude range, in which amplitudes of the output signals (e.g. output currents) of the second 106 and third 110 amplifiers increase substantially linearly across the second output amplitude range. In such examples, the first amplifier 102 may operate in voltage saturation in the second output amplitude range. However, due to the load modulation of the first amplifier 102, in some examples, the output signal (e.g. output current) may not be constant over the second output amplitude range, for example may increase across the second output amplitude range. The amplitudes of the output signals of the second 106 and third 110 amplifiers may in some examples increase substantially equally or equally across the second output amplitude range.

In some examples, the first amplifier 102 may comprise a balanced amplifier. Thus, for example, the first amplifier 102 may comprise a balanced amplifier that employs two identical amplifier branches, processing signals with identical magnitudes but 90 degrees out of phase. The 90-degree phase difference may be implemented for example by using 3-dB 90-degree hybrid couplers at the input (as a power splitter) and output (as a power combiner). Alternatively, for example, a non-90 degree power splitter and a non-90 degree power combiner may be used.

Alternatively, for example, the first amplifier 102 may be an amplifier circuit such as the amplifier circuit 100 shown in FIG. 1. That is, for example, the first amplifier 102 shown in FIG. 1 may itself contain further first, second and third amplifiers and a further directional coupler arranged in the configuration shown in FIG. 1. The output (represented as output 124 in FIG. 1) of this further amplifier circuit may then in some examples be connected to the input port 116 of the directional coupler 114 of the amplifier circuit 100 shown in FIG. 1.

FIG. 2 is a flow chart of an example of a method 200 of operating an amplifier circuit. The amplifier circuit comprises a first amplifier configured to receive a first signal, a second amplifier configured to receive a second signal and a third amplifier configured to receive a third signal. The amplifier circuit also includes a first directional coupler, wherein an output of the first amplifier is connected to a first port of the first directional coupler, an output of the third amplifier is connected to a second port of the first directional coupler, an output of the second amplifier is connected to a third port of the first directional coupler, and a fourth port of the first directional coupler is connected to an output of the amplifier circuit. The first, second and third signals are based on a signal to be amplified by the amplifier circuit, and the directional coupler is configured such that different proportions of output signals of the second and third amplifiers are coupled to the input port of the directional coupler. In some examples, the amplifier circuit is any of the examples of the amplifier circuit 100 shown in FIG. 1 and described above.

The method 200 comprises, in step 202, operating the amplifier circuit in a first output amplitude range in which the second and third amplifiers are substantially switched off and a amplitude of an output signal of the first amplifier increases substantially linearly across the first output amplitude range. In some examples, the method 200 may also comprise, in step 204, operating the amplifier circuit in a second output amplitude range, higher than the first output amplitude range, in which amplitudes of the output signals of the second and third amplifiers increase substantially linearly across the first output amplitude range. The method 200 may also in some examples comprise operating the first amplifier in saturation in the second output amplitude range.

In some examples, similar to the amplifier circuit 100, in the amplifier circuit referred to in the method 200 the first port comprises an input port of the first directional coupler, the second port comprises a transmitted port of the first directional coupler, the third port comprises a coupled port of the first directional coupler, and the fourth port comprises an isolated port of the first directional coupler. Alternatively, for example, the first port comprises a transmitted port of the first directional coupler, the second port comprises an input port of the first directional coupler, the third port comprises an isolated port of the first directional coupler, and the fourth port comprises a coupled port of the first directional coupler. In other examples, the first port comprises a coupled of the first directional coupler, the second port comprises an isolated port of the first directional coupler, the third port comprises an input port of the first directional coupler, and the fourth port comprises a transmitted port of the first directional coupler. In other examples, the first port comprises an isolated port of the first directional coupler, the second port comprises a coupled port of the first directional coupler, the third port comprises a transmitted port of the first directional coupler, and the fourth port comprises an input port of the first directional coupler. Thus for example the directional coupler may be connected in the amplifier circuit in various ways to provide the operations and advantages described herein.

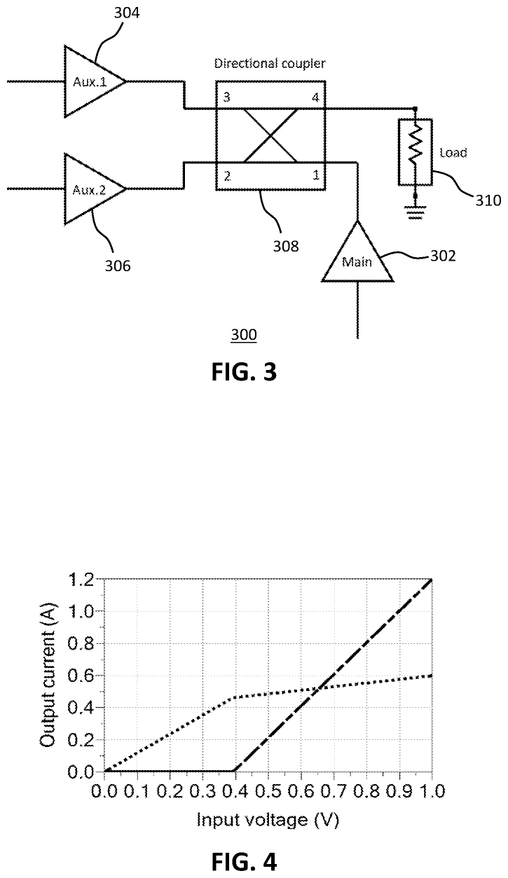

Particular embodiments will now be described FIG. 3 shows an example of an amplifier circuit 300, which consists of a main amplifier 302 and two identical auxiliary amplifiers 304 and 306. The amplifiers 302, 304 and 306 may correspond to the first, second and third amplifiers 102, 106 and 110 respectively in some examples. The output power of the main 302 and auxiliary 304, 306 amplifiers is combined by a directional coupler 308 and delivered to a load 310.

A directional coupler (such as for example the directional coupler 114 shown in FIG. 1 and/or the directional coupler 308 shown in FIG. 3) is a 4-port passive component that is ideally lossless. Such a directional coupler can be defined by its scattering parameters in some examples as:

$$[ S ] = [ \begin{matrix}0 & - ja & - b & 0 \\ - ja & 0 & 0 & - b \\ - b & 0 & 0 & - ja \\ 0 & - b & - ja & 0\end{matrix} ] ,$$

where j=\sqrt{−1}, and b is the coupling factor. Ideally the coupler is lossless, so |a|²+|b|²=1. If power is injected into port 1 (the input port), port 2, 3, 4 are the through (or transmitted), coupled and isolated port, respectively, as shown in FIG. 3. Such a coupler has many practical implementations, e.g. a branch-line coupler, a Lange coupler or a coupled-line coupler.

If the coupling factor is 3 dB, i.e. |a|=|b|, and the two aux. amplifiers 304 and 306 (or in some examples the amplifiers 106 and 110 shown in FIG. 1) are identical, the structure is S-LMBA in [1]. If the coupling factor is 3 dB and the two aux. amplifiers 304 and 306 operate at different power levels, the structure is A-LMBA [2]. For embodiments of this disclosure, the coupling factor is not 3 dB, i.e. |a|≠|b|, and the two aux. amplifiers 304 and 306 may be identical or substantially identical.

At a low power level, only the main amplifier 302 (or in some examples the first amplifier 102 shown in FIG. 1) is operating. The aux. amplifiers 304 and 306 are switched off, presenting as open circuits at port 2 and 3. The power from the main amplifier 302 goes out of port 2 and 3, but is fully reflected by the off-state aux. amplifiers 304 and 306 and then flows out of port 4 towards the load 310.

At the peak power level, both the main 302 and the aux. 304, 306 amplifiers are switched on. The power from the 3 amplifiers is combined in-phase at the load 310. To meet this in-phase combining requirement, the signals injected into ports 1, 2, and 3 should meet certain phase requirements. In an exemplary embodiment, the coupler 308 is implemented so that a and b are positive real numbers. Then, the aux. amplifier 304 has signal phase 0, aux. amplifier 306 has phase 90 degrees, and the main amplifier 302 has phase 180 degrees. They all reach the load at port 4 with phase −90 degrees and are combined in phase.

Note that the incident signals from aux. amplifiers 304, 306 at ports 2 and 3 are not only coupled to port 4 but also to port 1. More specifically, a signal from aux. amplifier 304 reaches port 1 with phase −180 and a signal from aux. amplifier 306 reaches port 1 at 0 degrees. Therefore, the signals from aux. amplifiers 304, 306 at port 1 are 180 degrees out of phase.

For S-LMBA ([1]), the signals from the auxiliary amplifiers are identical in magnitude, so they cancel each other completely at port 1. Therefore, the main amplifier at port 1 cannot have load modulation.

For A-LMBA ([2]), the coupler is 3 dB, i.e. |a|=|b|. To achieve load modulation at port 1, the outputs from the auxiliary amplifiers need to be different, so their signals at port 2 and 3 are different in magnitude. This causes the coupled signals from port 2 and 3 to port 1 to be different in magnitude, so they do not cancel each other completely. The residual power coming out of port 1 enables load modulation to the main amplifier.

In contrast, the proposed techniques employ identical or substantially identical auxiliary amplifiers, i.e. the aux. amplifiers 304 and 306 are substantially identical and inject signals with substantially the same magnitude at ports 2 and 3 respectively. Since |a|≠|b|, the signal coupled from port 2 to port 1 has a different magnitude compared with the signal coupled from port 3 to port 1. Because of this magnitude difference, these two signals at port 1 cannot cancel each other completely. The residual power coming out of port 1 enables load modulation to the main amplifier 302. Thus, in some examples, the directional coupler 308 in FIG. 3 may provide the same or similar effect of load modulation of the main amplifier 302 as the directional coupler 114 shown in FIG. 1, which may provide load modulation of the first amplifier 102. Thus, for example, port 1 in FIG. 3 may correspond to the first port 116 in FIG. 1, port 2 in FIG. 3 may correspond to the second port 120 in FIG. 1, port 3 in FIG. 3 may correspond to the third port 118 in FIG. 1, and port 4 in FIG. 3 may correspond to the fourth port 122 in FIG. 1.

FIGS. 4-7 illustrate an example of the operation of an exemplary embodiment of an amplifier circuit that consists of a 15 W main transistor (e.g. corresponding to the first amplifier 102 of FIG. 1 and/or the main amplifier 302 of FIG. 3) and two identical 30 W aux. transistors (e.g. corresponding to the second and third amplifiers 106, 110 of FIG. 1 and/or the aux. amplifiers 304, 306 shown in FIG. 3). The peak output power is 75 W. All transistors are biased with 50V DC drain voltage. The coupler has a coupling factor of 5.2 dB.

The output current of the three transistors vs. normalized input voltage is illustrated in FIG. 4. In FIGS. 4-7, curves associated with the main amplifier (e.g. 102 and/or 302) are shown as a dotted line, curves associated with the first aux. amplifier (e.g. 106 and/or 304) are shown as a dashed line, and curves associated with the second aux. amplifier (e.g. 110 and/or 306) are shown as a dash-dot line (which overlaps with the dashed line representing the output of the first aux. amplifier in FIG. 4). As shown in FIG. 4, the main transistor outputs a peak current of 0.6 A magnitude and the two aux. transistors each output a peak current of 1.2 A magnitude. The two aux. curves overlap, indicating that the two aux. devices generate identical current magnitude.

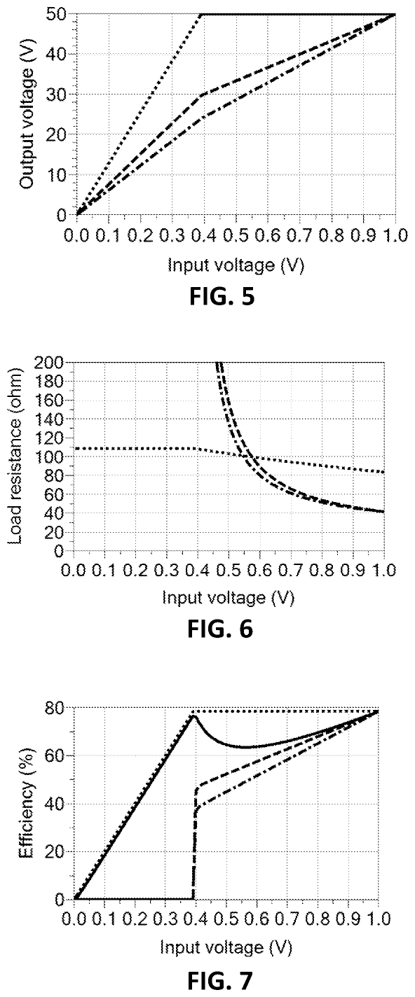

The output voltage of the three transistors vs. normalized input voltage is shown in FIG. 5. As shown in this figure, the main transistor reaches peak voltage at the back-off power level. This ensures efficiency enhancement at this power level. All transistors reach their peak voltage of 50 V at the peak power level.

The load resistance seen by the three transistors vs. normalized input voltage is shown in FIG. 6. As shown in this figure, the main transistor sees a load resistance of 109 ohm at low power and 84 ohm at the peak power level. This indicates a load modulation ratio of 109/84=1.3.

The efficiency of the three transistors and the total efficiency vs. normalized input voltage is shown in FIG. 7. As shown in this figure, the total efficiency reaches the theoretical maximum of 78.5% for a Class-B stage, not only at the peak power level but also at the back-off power level 8 dB below the peak level.

As such, examples of this disclosure may have one or more of the following properties:
Efficiency enhancement at deep power back-off (e.g. 8 dB below the peak power level for the example shown in FIGS. 4-7)
Moderate load modulation ratio (e.g. 109 ohm/84 ohm=1.3 for the example shown in FIGS. 4-7)
Identical aux. transistors (e.g. 50V 30 W devices for the example shown in FIGS. 4-7)
Full utilization of all transistors (e.g. 15+30+30=75 W for the example shown in FIGS. 4-7)

Other exemplary implementations are possible with arbitrary PAPR, load modulation ratio, supply voltages and power levels.

1. An amplifier circuit comprising:
a first amplifier configured to receive a first signal;
a second amplifier configured to receive a second signal;
a third amplifier configured to receive a third signal; and
a directional coupler;
wherein an output of the first amplifier is connected to a first port of the directional coupler, an output of the third amplifier is connected to a second port of the directional coupler, an output of the second amplifier is connected to a third port of the directional coupler, and a fourth port of the directional coupler is connected to an output of the amplifier circuit; and
wherein the directional coupler is configured such that different proportions of output signals of the second and third amplifiers are coupled to first the port of the directional coupler.

2. The amplifier circuit of claim 1, wherein:
the first port comprises an input port of the directional coupler, the second port comprises a transmitted port of the directional coupler, the third port comprises a coupled port of the directional coupler, and the fourth port comprises an isolated port of the directional coupler;
the first port comprises a transmitted port of the directional coupler, the second port comprises an input port of the directional coupler, the third port comprises an isolated port of the directional coupler, and the fourth port comprises a coupled port of the directional coupler;
the first port comprises a coupled of the directional coupler, the second port comprises an isolated port of the directional coupler, the third port comprises an input port of the directional coupler, and the fourth port comprises a transmitted port of the directional coupler; or
the first port comprises an isolated port of the directional coupler, the second port comprises a coupled port of the directional coupler, the third port comprises a transmitted port of the directional coupler, and the fourth port comprises an input port of the directional coupler.

3. The amplifier circuit of claim 1, wherein the directional coupler is configured such that the output signals of the second and third amplifiers only partially cancel at the first port of the directional coupler.

4. The amplifier circuit of claim 1, wherein a coupling factor of the directional coupler is a value other than 3 dB.

5. The amplifier circuit of claim 1, wherein the second and third amplifiers are substantially identical.

6. The amplifier circuit of claim 1, wherein the second signal is substantially identical to the third signal and substantially 90 degrees out of phase with the third signal.

7. The amplifier circuit of claim 1, wherein the first, second and third signals are based on a signal to be amplified by the amplifier circuit.

8. The amplifier circuit of claim 7, wherein the amplifier circuit is configured to operate in a first output amplitude range in which the second and third amplifiers are substantially switched off and an amplitude of an output signal of the first amplifier increases substantially linearly across the first output amplitude range.

9. The amplifier circuit of claim 8, wherein the amplifier circuit is configured to operate in a second output amplitude range, higher than the first output amplitude range, in which amplitudes of the output signals of the second and third amplifiers increase substantially linearly across the second output amplitude range.

10. The amplifier circuit of claim 9, wherein the first amplifier operates in voltage saturation in the second output amplitude range.

11. The amplifier circuit of claim 9, wherein the amplitudes of the output signals of the second and third amplifiers increase substantially equally across the second output amplitude range.

12. The amplifier circuit of claim 1, wherein the output signals of the second and third amplifiers comprise output currents.

13. The amplifier circuit of claim 1, wherein the first amplifier comprises a balanced amplifier.

14. (canceled)

15. A method of operating an amplifier circuit, wherein the amplifier circuit comprises:
a first amplifier configured to receive a first signal;
a second amplifier configured to receive a second signal;
a third amplifier configured to receive a third signal; and
a directional coupler;
wherein an output of the first amplifier is connected to a first port of the directional coupler, an output of the third amplifier is connected to a second port of the directional coupler, an output of the second amplifier is connected to a third port of the directional coupler, and a fourth port of the directional coupler is connected to an output of the amplifier circuit;
wherein the first, second and third signals are based on a signal to be amplified by the amplifier circuit, and the directional coupler is configured such that different proportions of output signals of the second and third amplifiers are coupled to the first port of the directional coupler; and
wherein the method comprises operating the amplifier circuit in a first output amplitude range in which the second and third amplifiers are substantially switched off and an amplitude of an output signal of the first amplifier increases substantially linearly across the first output amplitude range.

16. The method of claim 15, wherein:
the first port comprises an input port of the directional coupler, the second port comprises a transmitted port of the directional coupler, the third port comprises a coupled port of the directional coupler, and the fourth port comprises an isolated port of the directional coupler;
the first port comprises a transmitted port of the directional coupler, the second port comprises an input port of the directional coupler, the third port comprises an isolated port of the directional coupler, and the fourth port comprises a coupled port of the directional coupler;
the first port comprises a coupled of the directional coupler, the second port comprises an isolated port of the directional coupler, the third port comprises an input port of the directional coupler, and the fourth port comprises a transmitted port of the directional coupler; or
the first port comprises an isolated port of the directional coupler, the second port comprises a coupled port of the directional coupler, the third port comprises a transmitted port of the directional coupler, and the fourth port comprises an input port of the directional coupler.

17. The method of claim 15, comprising operating the amplifier circuit in a second output amplitude range, higher than the first output amplitude range, in which amplitudes of the output signals of the second and third amplifiers increase substantially linearly across the second output amplitude range.

18. (canceled)

19. An electronic device including an amplifier circuit comprising:
a first amplifier configured to receive a first signal;
a second amplifier configured to receive a second signal;
a third amplifier configured to receive a third signal; and
a directional coupler;
wherein an output of the first amplifier is connected to a first port of the directional coupler, an output of the third amplifier is connected to a second port of the directional coupler, an output of the second amplifier is connected to a third port of the directional coupler, and a fourth port of the directional coupler is connected to an output of the amplifier circuit; and
wherein the directional coupler is configured such that different proportions of output signals of the second and third amplifiers are coupled to the first port of the directional coupler.

20. The electronic device of claim 19, wherein:
the first port comprises an input port of the directional coupler, the second port comprises a transmitted port of the directional coupler, the third port comprises a coupled port of the directional coupler, and the fourth port comprises an isolated port of the directional coupler;
the first port comprises a transmitted port of the directional coupler, the second port comprises an input port of the directional coupler, the third port comprises an isolated port of the directional coupler, and the fourth port comprises a coupled port of the directional coupler;
the first port comprises a coupled of the directional coupler, the second port comprises an isolated port of the directional coupler, the third port comprises an input port of the directional coupler, and the fourth port comprises a transmitted port of the directional coupler; or
the first port comprises an isolated port of the directional coupler, the second port comprises a coupled port of the directional coupler, the third port comprises a transmitted port of the directional coupler, and the fourth port comprises an input port of the directional coupler.

21. The electronic device of claim 19, wherein the directional coupler is configured such that the output signals of the second and third amplifiers only partially cancel at the first port of the directional coupler.

22. The electronic device of claim 19, wherein a coupling factor of the directional coupler is a value other than 3 dB.
